(19) United States
(12) Patent Application Publication
(10) Pub. No.: US 2004/0005789 A1
(43) Pub. Date: Jan. 8, 2004

(54) Method for fabricating semiconductor device

(75) Inventors: Nobuhiro Jiwari, Osaka (JP); Shinichi Imai, Osaka (JP)

Correspondence Address: NIXON PEABODY, LLP, 401 9TH STREET, NW, SUITE 900, WASINGTON, DC, 20004-2128, US

(73) Assignee: MATSUSHITA ELECTRIC INDUSTRIAL CO., LTD., Osaka (JP)

(21) Appl. No.: 10/600,606

(22) Filed: Jun. 23, 2003

Related U.S. Application Data
(62) Division of application No. 09/708,086, filed on Nov. 8, 2000.

(30) Foreign Application Priority Data
Nov. 10, 1999 (JP) 11-319086

(51) Int. Cl. H01L 21/4763; H01L 21/31; H01L 21/469

(52) U.S. Cl. 438/780; 438/623

(57) ABSTRACT

A fluorine-containing organic film having a relative dielectric constant of 4 or less is deposited on a semiconductor substrate using a material gas containing C₅F₈, C₃F₆, or C₄F₆ as a main component.

### BACKGROUND OF THE INVENTION

The present invention relates to a method for fabricating a semiconductor device that includes a fluorine-containing organic film having a low relative dielectric constant.

With recent remarkable progress in semiconductor process technology, finer semiconductor elements and metal interconnections with higher integration have been pursued. With this trend toward finer size and higher integration, signal delay at metal interconnections has come to greatly influence the operation speed of semiconductor integrated circuits.

In the above situation, desired is a technique of depositing a fluorine-containing organic film (fluorocarbon film) that contains carbon atoms and fluorine atoms as main components and has a relative dielectric constant lower than that of an inorganic film such as a SiO₂ film or a SiOF film.

There is known a method for depositing a fluorine-containing organic film by plasma CVD using CF₄ gas, C₂F₆ gas, C₃F₈ gas, or C₄F₈ gas as a material gas. The fluorine-containing organic film obtained by this method has a relative dielectric constant of about 2, which is lower than the relative dielectric constant of the SiOF film mentioned above (about 3.5 to 3.8). Accordingly, by depositing such a fluorine-containing organic film between metal interconnections or on the top surfaces of metal interconnections, signal delay at the metal interconnections can be reduced.

However, a fluorine-containing organic film deposited using any of the above fluorine-containing material gases is disadvantageously poor in adhesion to an underlying film and thus easily peels off.

In order to solve the above problem, Japanese Laid-open Patent Publication No. 8-83842 proposes a method for depositing a fluorine-containing organic film as follows. Initially in a film formation process, a hydrocarbon-base gas such as CH₄, C₂H₄, or C₂H₂ is introduced, and midway in the film formation process, a fluorine-base gas such as CF₄, C₂F₆, C₃F₈, or C₄F₈ is mixed in the hydrocarbon-base gas. The resultant film contains no fluorine in the portion thereof at and near the interface with a substrate, but contains fluorine inside the film. According to this method, since no fluorine atoms exist in the portion of the fluorine-containing organic film at and near the interface with the substrate, the adhesion of the film to the substrate can be improved.

The above film formation method however has the following problems. The composition of the material gas must be changed midway in the film formation process. This disadvantageously complicates the process.

The other problem is that the mixed gas containing fluorine atoms (perfluoro-compound gas (PFC)) described above has a large global warming potential (GWP₁₀₀) and thus has a possibility of causing global warming due to the greenhouse effect if used in high volume in an industrial scale.

### SUMMARY OF THE INVENTION

In view of the above, the object of the present invention is allowing a fluorine-containing organic film to be deposited without complicating a film -formation process and without causing global warming.

In order to attain the above object, the inventors of the present invention examined PFCs in search for a PFC having a small global warming potential usable as a material gas in a plasma CVD method, and found that C₅F₈ gas, C₃F₆ gas, and C₄F₆ gas are usable as such a material gas.

Table 1 below shows the relationships of various gases with the atmospheric life and the GWP₁₀₀ (value obtained by quantifying the warming ability over 100 years of a gas with respect to that of carbon dioxide as 1).

TABLE 1

| | | Atmospheric | |
|---|---|---|---|
| Kind of gas | Formula | life (year) | GWP₁₀₀ |
| Carbon dioxide | CO₂ | 170 | 1 |
| Tetrafluoromethafle | CF₄ | 50000 | 6500 |
| Hexafluoroethafle | C₂F₆ | 10000 | 9200 |
| Trifluoromethafle | CHF₃ | 250 | 12100 |
| Octafluoropropane | C₃F₈ | 2600 | 7000 |
| Octafluorocyclobutane | C₄F₈ | 3200 | 8700 |
| Octafluorocyclopentene | C₅F₈ | 1 | 90 |
| Hexafluoropropene | C₃F₆ | less than 1 | less than 100 |
| | | | (estimation) |
| Hexafluoropropane | C4F6 | less than 1 | less than 100 |
| | | | (estimation) |

As is found from Table 1, C₅F₈ gas, C₃F₆ gas, and C₄F₆ gas are short in atmospheric life and small in GWP₁₀₀, and therefore do not easily cause global warming.

Also, it was found that a fluorine-containing organic film deposited using C₅F₈ gas, C₃F₆ gas, or C₄F₆ gas as a material gas exhibited adhesion to an underlying film superior to that of a fluorine-containing organic film deposited using CF₄ gas, C₂F₆ gas, C₂F₈ gas, or C₄F₈ gas.

The inventors examined the reason why the former fluorine-containing organic film was superior to the latter fluorine-containing organic film in adhesion to an underlying film. As a result, the reason was found to be that the number of free fluorine atoms contained in the former fluorine-containing organic film was smaller than the number of free fluorine atoms contained in the latter fluorine-containing organic film. The present invention was attained based on these findings.

The first method for fabricating a semiconductor device of the present invention includes the step of: depositing a fluorine-containing organic film having a relative dielectric constant of 4 or less on a semiconductor substrate using a material gas containing C₅F₈, C₃F6, or C₄F₆ as a main component.

According to the first method for fabricating a semiconductor device, the main component of the material gas is C₅F₈, C₃F₆, or C₄F₆ having a small global warming potential. Therefore, the possibility of causing global warming is reduced. In addition, the fluorine-containing organic film obtained by the first fabrication method is small in the number of free fluorine atoms contained in the film, compared with a fluorine-containing organic film deposited using a conventionally known fluorine-base gas such as CF₄, C₂F₆, C₃F₈, or C₄F₈. Therefore, the adhesion of the film to the semiconductor substrate improves.

The second method for fabricating a semiconductor device of the present invention includes the steps of: dry-etching an insulating film on a semiconductor substrate using an etching gas containing C₅F₈, C₃F₆, or C₄F₆ as a main component; and depositing a fluorine-containing organic film having a relative dielectric constant of 4 or less on the semiconductor substrate using a material gas containing C₅F₈, C₃F₆, or C₄F₆ as a main component, wherein the step of dry-etching an insulating film and the step of depositing a fluorine-containing organic film are performed in a same plasma processing apparatus.

According to the second method for fabricating a semiconductor device, in addition to the effect obtained by the first fabrication method, the following effect can be obtained. The step of dry-etching an insulating film and the step of depositing a fluorine-containing organic film are performed in a same plasma processing apparatus. This eliminates the necessity of transporting the semiconductor substrate from an etching apparatus to a film formation apparatus. As a result, the possibility of attachment of particles to the semiconductor substrate during the transportation is eliminated, and thus the yield improves. In addition, the number of process steps is reduced and thus the fabrication time is shortened.

In the second fabrication method, the step of dry-etching an insulating film and the step of depositing a fluorine-containing organic film are preferably performed in a same reactor chamber of the same plasma processing apparatus. This further reduces attachment of particles and also further shortens the fabrication time.

In the second fabrication method, preferably, the step of dry-etching an insulating film includes the step of forming a contact hole through the insulating film, the step of depositing a fluorine-containing organic film includes the step of filling at least a bottom portion of the contact hole with the fluorine-containing organic film, and after the step of depositing a fluorine-containing organic film, the method further includes the steps of: forming a resist pattern having an opening for wiring groove formation on the insulating film; forming a wiring groove on the insulating film by dry-etching the insulating film using the resist pattern as a mask; removing the resist pattern and the fluorine-containing organic film existing in the contact hole; and filling the contact hole and the wiring groove with a metal film to form a contact and a metal interconnection made of the metal film.

By the above steps, in a so-called dual damascene process of forming embedded interconnections, it is possible to perform the step of forming a contact hole through the insulating film and the step of filling the contact hole with the fluorine-containing organic film in a same plasma processing apparatus. In general, in the dual damascene process, after formation of a hole, the hole is filled with a resist film or a reflection prevention film by coating application. According to the second method for fabricating a semiconductor device, the fluorine-containing organic film functions as an etching stopper film. This eliminates the step of depositing an etching stopper film under the insulating film and the step of removing the portion of the etching stopper film exposed at the bottom of the contact hole. Thus, the number of process steps can be reduced.

The third method for fabricating a semiconductor device of the present invention includes the steps of: depositing a metal film on a semiconductor substrate; forming a mask pattern made of a resist film or an insulating film on the metal film; dry-etching the metal film using the mask pattern to form a plurality of metal interconnections made of the metal film; and depositing a fluorine-containing organic film having a relative dielectric constant of 4 or less as an interlayer insulating film between the plurality of metal interconnections and on top surfaces of the metal interconnections using a material gas containing C₅F₈, C₃F₆, or C₄F₆ as a main component.

According to the third method for fabricating a semiconductor device, in addition to the effect obtained by the first fabrication method, it is possible to improve the adhesion of the interlayer insulating film made of the fluorine-containing organic film to the metal interconnections. Moreover, since the relative dielectric constant of the interlayer insulating film made of the fluorine-containing organic film is low, signal delay at the metal interconnections can be reduced.

In the third fabrication method, preferably, the step of forming a mask pattern includes the steps of: depositing the insulating film on the metal film; forming a resist pattern on the insulating film; and dry-etching the insulating film using the resist pattern to form the mask pattern, and the step of dry-etching the insulating film and the step of depositing a fluorine-containing organic film are performed in a same reactor chamber of a same plasma processing apparatus.

By the above steps, it is no more required to transport the semiconductor substrate from an etching apparatus to a film formation apparatus. This eliminates the possibility of attachment of particles to the semiconductor substrate during the transportation, and thus the yield improves. In addition, the number of process steps is reduced and thus the fabrication time is shortened.

In the second or third fabrication method, the step of dry-etching the metal film is preferably performed in the same reactor chamber.

By using the same reactor chamber, attachment of particles can be further reduced, and the fabrication time can be further shortened.

In the above case, the inner wall of the same reactor chamber preferably includes an aluminum layer and a ceramic layer or an Alumite-treated (anodized) aluminum layer.

With the above construction, even when an etching gas that can etch metal materials, such as Cl₂ gas, is used in the process of dry-etching the metal film, the inner wall of the reactor chamber is prevented from being etched. Thus, a problem of the inner wall being injured or the etching conditions being changed is prevented.

In the second or third fabrication method, the insulating film is preferably made of a silicon oxide film.

Use of a silicon oxide film facilitates common use of a same gas as the etching gas in the step of dry-etching an insulating film and the material gas in the step of depositing a fluorine-containing organic film. This makes it easy to perform the step of dry-etching an insulating film and the step of depositing a fluorine-containing organic film in a same plasma processing apparatus.

### BRIEF DESCRIPTION OF THE DRAWINGS

FIG. 1 is a cross-sectional view of the entire construction of an inductively coupled plasma processing apparatus used for embodiments of the method for fabricating a semiconductor device of the present invention.

FIGS. 2(a) through 2(e) are cross-sectional views illustrating steps of the method for fabricating a semiconductor device of the first embodiment of the present invention.

FIGS. 3(a) through 3(d) are cross-sectional views illustrating steps of the method for fabricating a semiconductor device of the second embodiment of the present invention.

FIGS. 4(a) through 4(d) are cross-sectional views illustrating steps of the method for fabricating a semiconductor device of the second embodiment of the present invention.

FIG. 5 is a view showing the XPS measurement results of fluorine-containing organic films deposited using C₅F₈ gas, C₂F₆ gas, and C₄F₈ gas.

FIGS. 6(a) through 6(d) are cross-sectional views illustrating steps of a conventional method for fabricating a semiconductor device.

FIGS. 7(a) through 7(d) are cross-sectional views illustrating steps of the conventional method for fabricating a semiconductor device.

### DESCRIPTION OF THE PREFERRED EMBODIMENTS

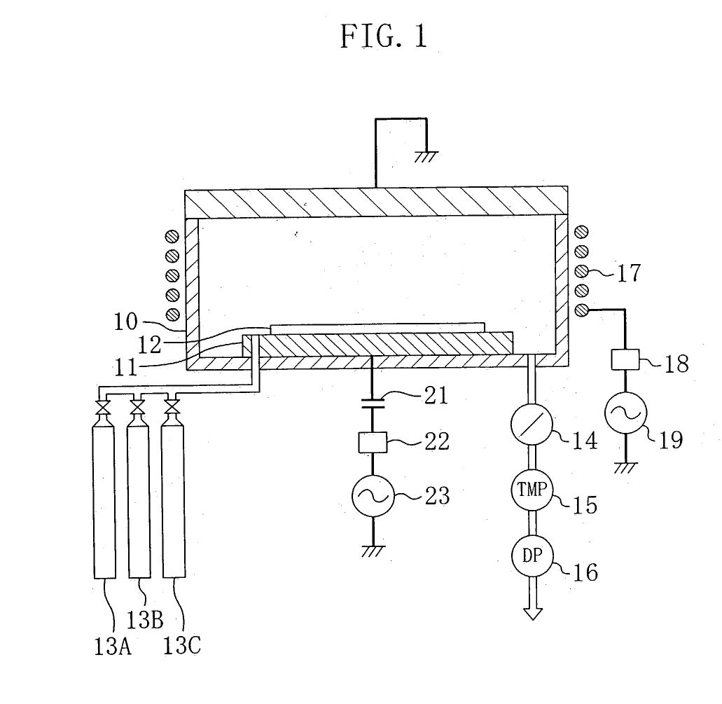

Hereinafter, an inductively coupled plasma processing apparatus used for the embodiments of the method for fabricating a semiconductor device of the present invention will be described with reference to FIG. 1.

FIG. 1 is a cross-sectional structure of the inductively coupled plasma processing apparatus where a bottom electrode 11 as a sample stage is disposed on the bottom of a reactor chamber 10 and holds a semiconductor substrate 12 thereon.

To the reactor chamber 10, connected are a first gas bottle 13A, a second gas bottle 13B, and a third gas bottle 13C for supply of C₅F₈ gas, Ar gas, and O₂ gas, respectively, so that C₅F₈ gas, Ar gas, and O₂ gas are introduced into the reactor chamber 10 at controlled flow rates from the first, second, and third gas bottles 13A, 13B, and 13C. The reactor chamber 10 is also provided with a gas exhaust means essentially composed of an outlet open/close valve 14, a turbo molecular pump (TMP) 15, and a dry pump (DP) 16.

A columnar coil 17 is wound around the outer circumference of a sidewall of the reactor chamber 10. An end of the columnar coil 17 is connected to a first high-frequency power source 19 via a first matching circuit 18, and the other end of the columnar coil 17 is connected to the sidewall of the reactor chamber 10 and thus grounded. Once a high-frequency power is applied to the columnar coil 17 from the first high-frequency power source 19, a high-frequency inductive electromagnetic field is generated in the reactor chamber 10, whereby the C₅F₈ gas, the Ar gas, and the O₂ gas in the reactor chamber 10 are changed to plasma. A second high-frequency power source 23 is connected to the bottom electrode 11 via a capacitor 21 and a second matching circuit 22. Once a high-frequency power is applied to the bottom electrode 11 from the second high-frequency power source 23, particles generated in the reactor chamber 10 move toward the bottom electrode 11, that is, toward the semiconductor substrate 12.

The plasma processing apparatus described above is characterized in that the inner wall of the reactor chamber 10 is essentially composed of an external aluminum layer and an internal ceramic layer or an Alumite-treated aluminum layer.

(First Embodiment)

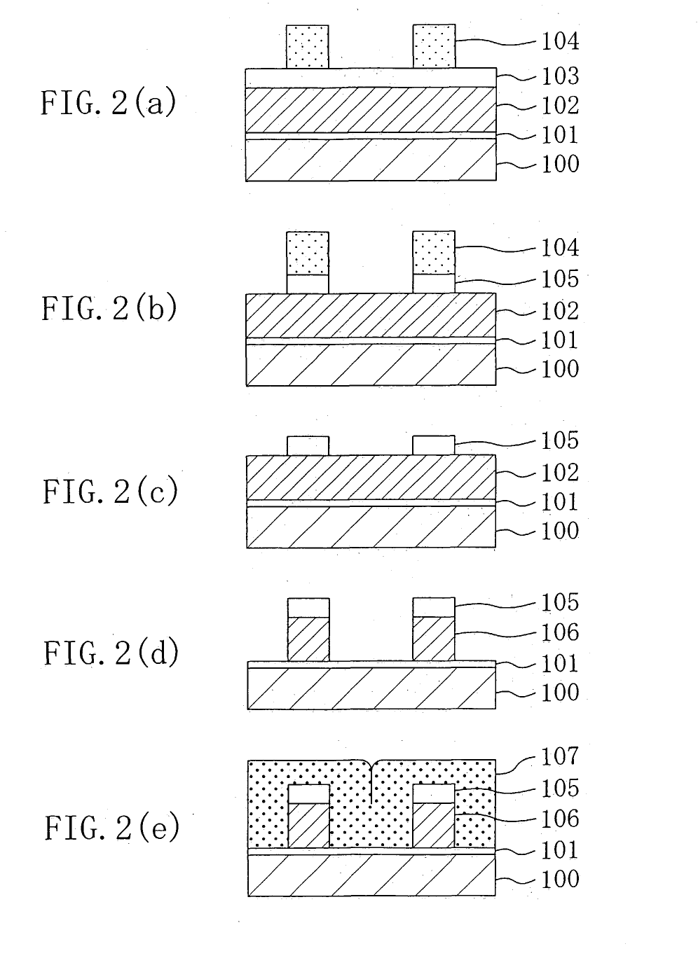

Hereinafter, the method for fabricating a semiconductor device of the first embodiment of the present invention, which uses the inductively coupled plasma processing apparatus described above, will be described with reference to FIGS. 1 and 2(a) through 2(e).

First, as shown in FIG. 2(a), formed sequentially on a semiconductor substrate 100 made of silicon are: a first silicon oxide film 101 made of a thermally oxidized film, for example; a metal film 102 made of aluminum or copper, for example; and a second silicon oxide film 103 made of TEOS, for example. Thereafter, a resist film is applied to the surface of the second silicon oxide film 103, and then subjected to a known photolithographic process to form a resist pattern 104 having a shape corresponding to a wiring pattern. The resultant semiconductor substrate 100 is mounted on the bottom electrode 11 of the plasma processing apparatus shown in FIG. 1 and held thereon by static adsorption.

Subsequently, to the reactor chamber 10 shown in FIG. 1, introduced are C₅F₈ gas from the first gas bottle 13A, Ar gas from the second gas bottle 13B, and O₂ gas from the third gas bottle 13C. Simultaneously, a first high-frequency power of 400 to 3000 W having a frequency of 2.0 MHz, for example, is applied to the columnar coil 17 from the first high-frequency power source 19, to generate C₅F₈/Ar/O₂ plasma in the reactor chamber 10. The mixture ratio of the C₅F₈ gas to the Ar gas is preferably in the range of 1:4 to 1:300 in volume flow rate, and the O₂ gas is preferably mixed in an amount of 5 vol. % or more with respect to the flow rate of the C₅F₈ gas.

A second high-frequency power of 0.5 to 7.0 W/cm² (power per wafer area of 1 cm²) having a frequency of 1.8 MHz, for example, is applied to the bottom electrode 12 from the second high-frequency power source 23, to attract etching species in the C₅F₈/Ar/O₂ plasma to the semiconductor substrate 100. This enables the second silicon oxide film 103 to be selectively dry-etched, thereby forming a hard mask 105 made of the second silicon oxide film 103 as shown in FIG. 2(b).

The supply of the C₅F₈ gas and the Ar gas is then stopped, while the flow rate of the O₂ gas is increased, to generate O₂ plasma in the reactor chamber 10. With the O₂ plasma, the resist pattern 104 is removed with ashing as shown in FIG. 2(c).

Although not shown, the connection is switched from the first, second, and third gas bottles 13A, 13B, and 13C to another gas bottle containing known etching gas such as Cl₂ gas, HBr gas, C₂F₆ gas, or the like to introduce such gas into the reactor chamber 10. With the etching gas, the metal film 102 is dry-etched using the hard mask 105 as a mask, to form metal interconnections 106 made of the metal film 102 as shown in FIG. 2(d).

The inner wall of the reactor chamber 10 has an inner liner formed of a ceramic layer as described above. Accordingly, even when an etching gas that can etch metal materials, such as Cl₂ gas, is used in the process of dry-etching the metal film 102, the inner wall of the reactor chamber 100 is prevented from being etched. This prevents a trouble such as the inner wall being injured or the etching conditions being changed.

Thereafter, the connection of the gas bottles is switched to the first and second gas bottles 13A and 13B, to introduce the C₅F₈ gas and the Ar gas. Simultaneously, the first high-frequency power of 400 to 3000 W having a frequency of 2.0 MHz, for example, is applied to the columnar coil 17 from the first high-frequency power source 19, to generate C₅F₈/Ar plasma in the reactor chamber 10. The mixture ratio of the C₅F₈ gas to the Ar gas is preferably in the range of 1:1 to 1:10 in volume flow rate. The O₂ gas may not be mixed, or may be mixed to some extent depending on the deposition conditions.

The second high-frequency power of 0 to 7.0 W/cm² having a frequency of 1.8 MHz, for example, is applied (the second high-frequency power may not be applied) to the bottom electrode 12 from the second high-frequency power source 23. As a result, an interlayer insulating film 107 made of a fluorine-containing organic film having a relative dielectric constant of 4 or less is deposited over the entire surface of the resultant semiconductor substrate 100 as shown in FIG. 2(e).

In the first embodiment, the C₅F₈ gas used as a material gas in the film formation process has a short atmospheric life and a small GWP₁₀₀ as is found from Table 1 above. Therefore, this gas will not cause global warming.

Using the C₅F₈ gas as a material gas for deposition of the fluorine-containing organic film, the number of free fluorine atoms contained in the deposited film is small, compared with a fluorine-containing organic film deposited using a fluorine-base gas such as CF₄, C₂F₆, C₃F₆, or C₄F₈. This improves the adhesion of the interlayer insulating film 107 to the metal interconnections 106 and the first silicon oxide film 101.

In addition, the fluorine-containing organic film deposited using the C₅F₈ gas is small in relative dielectric constant compared with the fluorine-containing organic film deposited using C₂F₆ gas or C₄F₈ gas. The reason is as follows.

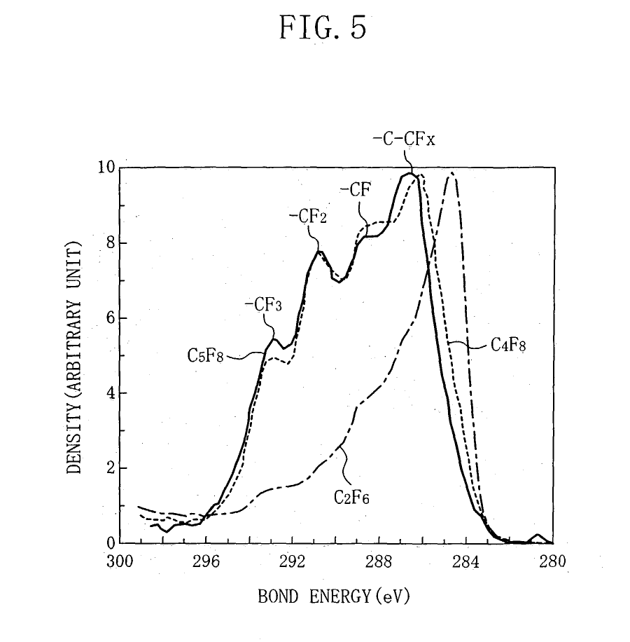

FIG. 5 shows the results of XPS measurement of fluorine-containing organic films deposited using C₅F₈ gas, C₂F₆ gas, and C₄F₈ gas. From FIG. 5, it is confirmed that the amount of fluorine atoms contained in the fluorine-containing organic film deposited using C₅F₈ gas is larger than that in the fluorine-containing organic film deposited using C₂F₆ gas or C₄F₈ gas.

The reason why the number of fluorine atoms is large in the film formed using C₅F₈ gas is as follows. C₅F₈ gas has a large gas molecular weight. Therefore, when plasma is generated using C₅F₈ gas, the number of fluorine atoms in a CₓF_{y} molecule constituting the resultant organic film is large.

For example, in comparison between C₂F₆ gas and C₅F₈ gas, C₂F₆ and C₅F₈ dissociate as follows.

C₂F₆→C₂F₅↓+F↑

C₅F₈→C₅F₇↓+F↑

C₂F₅and C₅F₇ constitute organic films. Therefore, naturally, the film formed by deposition of C₅F₇ contains a larger amount of fluorine atoms than the film formed by deposition of C₂F₅.

Accordingly, the interlayer insulating film 107 made of the fluorine-containing organic film deposited using the C₅F₈ gas is smaller in capacitance between interconnections than an interlayer insulating film made of the fluorine-containing organic film deposited using C₂F₆ gas or C₄F₈ gas. This reduces wiring delay at the metal interconnections 106.

Moreover, in the first embodiment, the C₅F₈ gas known as an etching gas is also used as a material gas for film formation. It is therefore possible to perform the process of selectively dry-etching the second silicon oxide film 103 to form the hard mask 105 and the process of depositing the interlayer insulating film 107 made of a fluorine-containing organic film in the same reactor chamber 10 of the same plasma processing apparatus. This eliminates the necessity of transporting the semiconductor substrate 100 from an etching apparatus to a film formation apparatus. As a result, the possibility of attachment of particles to the semiconductor substrate during the transportation is eliminated, and thus the yield improves. In addition, the fabrication time is shortened.

It is especially preferable to perform the process of dry-etching the second silicon oxide film 103 and the process of depositing the interlayer insulating film 107 made of a fluorine-containing organic film in the same reactor chamber 10. Alternatively, however, these processes may be performed in different reactor chambers in a multi-chamber plasma processing apparatus.

In the first embodiment, C₅F₈ gas was used as an etching gas and a material gas for film formation. Alternatively, C₃F₆ gas or C₄F₆ gas may be used. C₃F₆ gas and C₄F₆ gas are short in atmospheric life and small in GWP₁₀₀, compared with other fluorine-base gases such as CF₄ gas, C₂F₆ gas, C₃ F₈ gas, and C₄F₈ gas. In addition, fluorine-containing organic films deposited using C₃F₆ gas and C₄F₆ gas have superior adhesion and low relative dielectric constant, compared with fluorine-containing organic films deposited using other fluorine-base gases. This is presumably due to the C/F ratio of the gas and the molecular structure (especially, existence of carbon-to-carbon double bonds) of the gas.

In the first embodiment, the temperature of the bottom electrode 11 was not specified in particular. During etching, however, if the temperature of the bottom electrode 11 is raised to raise the temperature of the semiconductor substrate 100, the etching rate increases. During deposition, if the temperature of the bottom electrode 11 is lowered to lower the temperature of the semiconductor substrate 100, the resultant fluorine-containing organic film becomes dense.

In the first embodiment, the resist pattern 104 was removed by ashing using O₂ plasma. Alternatively, the resist pattern 104 may be removed during the process of dry-etching the metal film 102.

In the first embodiment, the hard mask 105 made of the second silicon oxide film 103 was used for the dry etching of the metal film 102 to form the metal interconnections 106. Alternatively, the hard mask 105 may not be used, but the resist pattern 104 may be used for the dry etching of the metal film 102.

(Second Embodiment)

Hereinafter, the method for fabricating a semiconductor device of the second embodiment of the present invention, which uses the inductively coupled plasma processing apparatus described above, will be described with reference to FIGS. 1, 3(a) through 3(d), and 4(a) through 4(d).

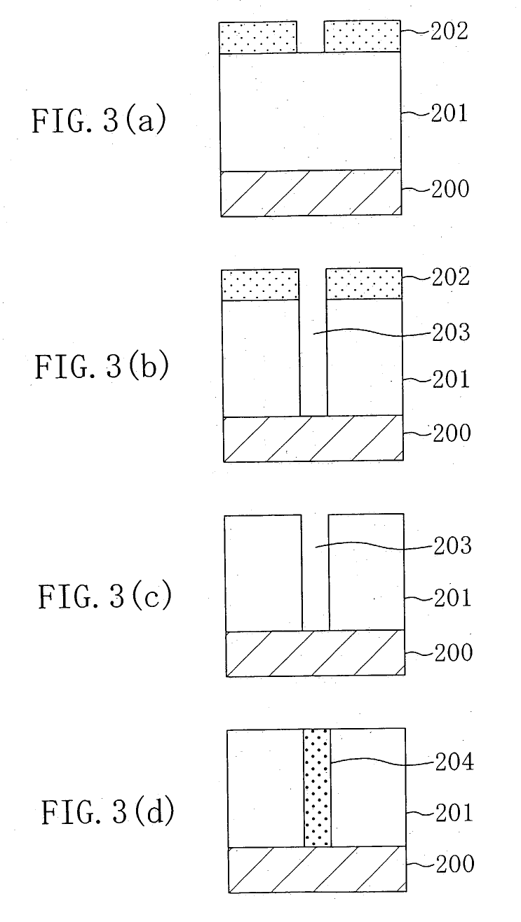

As shown in FIG. 3(a), a silicon oxide film 201 as an insulating film is formed on a semiconductor substrate 200 made of silicon, and then a first resist pattern 202 having openings for formation of contact holes is formed on the silicon oxide film 201. The resultant semiconductor substrate 200 is mounted on the bottom electrode 11 of the plasma processing apparatus shown in FIG. 1 and held thereon by static adsorption.

Subsequently, to the reactor chamber 10 shown in FIG. 1, introduced are C₅F₈ gas from the first gas bottle 13A, Ar gas from the second gas bottle 13B, and O₂ gas from the third gas bottle 13C. Simultaneously, a first high-frequency power of 400 to 3000 W having a frequency of 2.0 MHz, for example, is applied to the columnar coil 17 from the first high-frequency power source 19, to generate C₅F₈/Ar/O₂ plasma in the reactor chamber 10. The mixture ratio of the C₅F₈ gas to the Ar gas is preferably in the range of 1:4 to 1:300 in volume flow rate, and the O₂ gas is preferably mixed in an amount of 5 vol. % or more with respect to the flow rate of the C₅F₈ gas.

A second high-frequency power of 0.5 to 7.0 W/cm² having a frequency of 1.8 MHz, for example, is applied to the bottom electrode 12 from the second high-frequency power source 23, to attract etching species in the C₅F₈/Ar/O₂ plasma to the semiconductor substrate 200. This enables the silicon oxide film 201 to be selectively dry-etched using the first resist pattern 202 as a mask, thereby forming a contact hole 203 through the silicon oxide film 201 as shown in FIG. 3(b). Thereafter, as shown in FIG. 3(c), the first resist pattern 202 is removed by ashing using O₂ plasma.

While the supply of the C₅F₈ gas from the gas bottle 13A and the Ar gas from the gas bottles 13B is continued, the supply of the O₂ gas from the gas bottle 13C is stopped. Simultaneously, the first high-frequency power of 400 to 3000 W having a frequency of 2.0 MHz, for example, is applied to the columnar coil 17 from the first high-frequency power source 19, to generate C₅F₈/Ar plasma in the reactor chamber 10. The mixture ratio of the C₅F₈ gas to the Ar gas is preferably in the range of 1:1 to 1:10 in volume flow rate. The O₂ gas may not be mixed, or may be mixed to some extent depending on the deposition conditions.

The second high-frequency power of 0 to 7.0 W/cm² having a frequency of 1.8 MHz, for example, is applied to the bottom electrode 12 from the second high-frequency power source 23, to deposit a fluorine-containing organic film 204 having a relative dielectric constant of 4 or less on the silicon oxide film 201 so as to fill at least the bottom portion of the contact hole 203 with the fluorine-containing organic film as shown in FIG. 3(d).

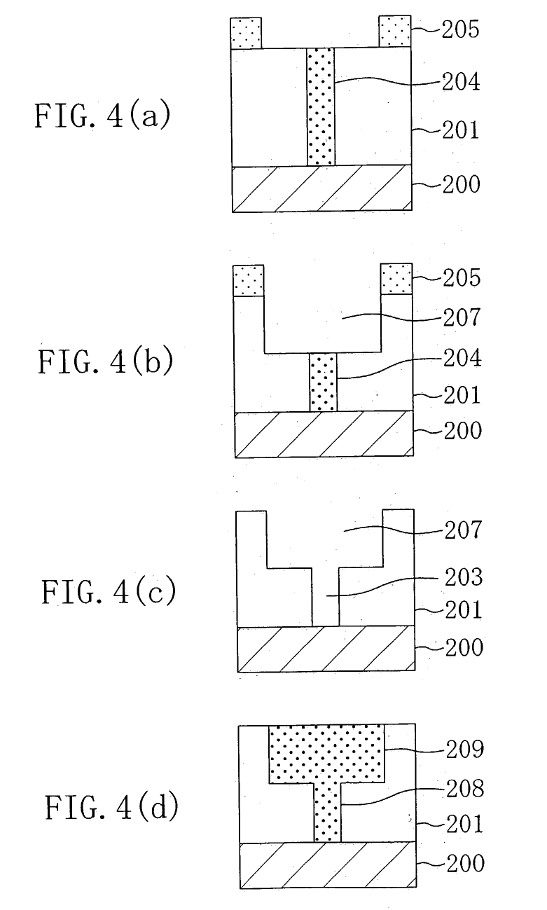

Thereafter, as shown in FIG. 4(a), a second resist pattern 205 having openings for wiring grooves is formed on the silicon oxide film 201.

Subsequently, introduced to the reactor chamber are C₅F₈ gas from the first gas bottle 13A, Ar gas from the second gas bottle 13B, and O₂ gas from the third gas bottle 13C. Simultaneously, the first high-frequency power of 400 to 3000 W having a frequency of 2.0 MHz, for example, is applied to the columnar coil 17 from the first high-frequency power source 19, to generate C₅F₈/Ar/O₂ plasma in the reactor chamber 10. The mixture ratio of the C₅F₈ gas to the Ar gas is preferably in the range of 1:4 to 1:300 in volume flow rate, and the O₂ gas is preferably mixed in an amount of 5 vol. % or more with respect to the flow rate of the C₅F₈ gas.

The second high-frequency power of 0.5 to 7.0 W/cm² having a frequency of 1.8 MHz, for example, is applied to the bottom electrode 12 from the second high-frequency power source 23, to attract etching species in the C₅F₈/Ar/O₂ plasma to the semiconductor substrate 200. This enables the silicon oxide film 201 to be dry-etched using the second resist pattern 202 as a mask, thereby forming a wiring groove 207 as shown in FIG. 4(b). During this etching, the fluorine-containing organic film 204 functions as an etching stopper while being gradually etched.

Thereafter, as shown in FIG. 4(c), the second resist pattern 205 and the fluorine-containing organic film 204 remaining in the contact hole 203 are removed by ashing using O₂ plasma. The fluorine-containing organic film 204 contains the organic substance as a main component, as well as the second resist pattern 205, and thus is removed with O₂ plasma without fail. Therefore, no separate etching process is required for removing the fluorine-containing organic film 204.

A metal film is then deposited over the entire surface of the silicon oxide film 201, and the portion of the metal film located on the top surface of the silicon oxide film 201 is removed. Thus, a semiconductor device having a dual damascene structure including a contact 208 and an embedded interconnection 209 both made of the metal film is formed as shown in FIG. 4(d).

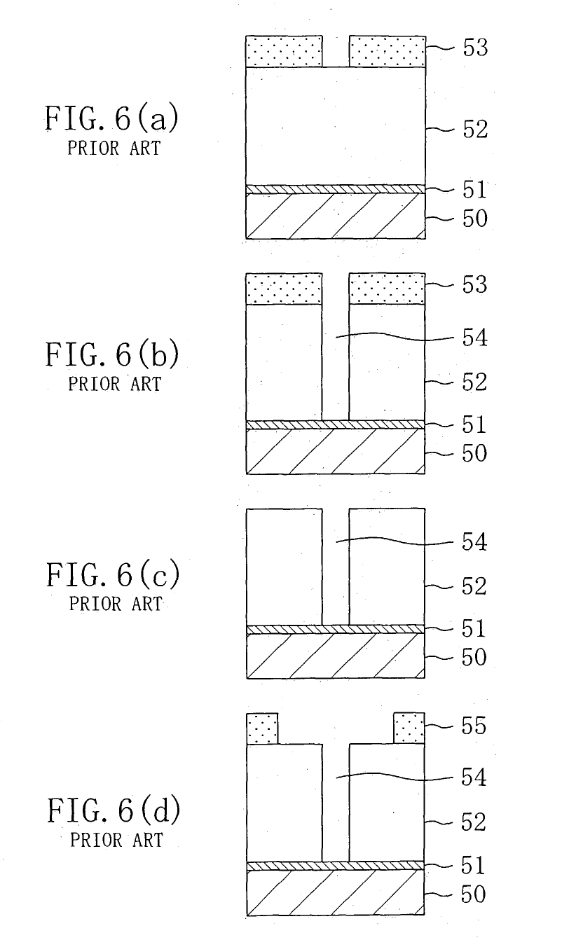

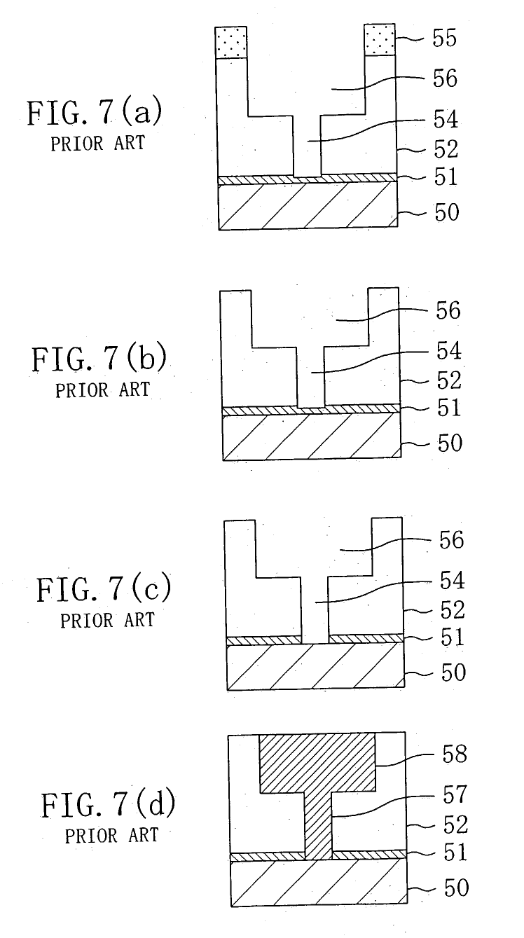

Hereinafter, to clarify the effect of the semiconductor device of the second embodiment, a conventional method for fabricating a semiconductor device having a dual damascene structure will be described with reference to FIGS. 6(a) through 6(d) and 7(a) through 7(d) as a comparative example.

As shown in FIG. 6(a), sequentially formed on a semiconductor substrate 50 are a silicon nitride film 51 to serve as an etching stopper and a silicon oxide film 52 to serve as an insulating film. A first resist pattern 53 having openings for formation of contact holes is then formed on the silicon oxide film 52.

Thereafter, the silicon oxide film 52 is dry-etched using the first resist pattern 53 as a mask and the silicon nitride film 51 as an etching stopper, to form a contact hole 54 through the silicon oxide film 52 as shown in FIG. 6(b). The first resist pattern 53 is then removed as shown in FIG. 6(c).

As shown in FIG. 6(d), a second resist pattern 55 having openings for wiring grooves is formed on the silicon oxide film 52. The silicon oxide film 52 is then dry-etched using the second resist pattern 55 as a mask and the silicon nitride film 51 as an etching stopper, to form a wiring groove 56 on the silicon oxide film 52 as shown in FIG. 7(a). The second resist pattern 55 is then removed as shown in FIG. 7(b).

Thereafter, the silicon nitride film 51 is dry-etched using the silicon oxide film 52 as a mask, to expose part of the semiconductor substrate 50 through the contact hole 54. A metal film is then deposited over the entire surface of the silicon oxide film 52, and the portion of the metal film located on the top surface of the silicon oxide film 52 is removed. Thus, a contact 57 and an embedded interconnection 58 both made of the metal film are formed as shown in FIG. 7(d).

As is found from comparison of the second embodiment with the comparative example, the second embodiment does not require the process of forming the silicon nitride film 51 and the process of etching the silicon nitride film 51. Actually, the second embodiment requires the process of depositing the fluorine-containing organic film 204 and the process of removing the fluorine-containing organic film 204 remaining in the contact hole 203. However, the deposition of the fluorine-containing organic film 204 can be performed in a film formation process using the material gas containing C₅F₈ gas as a main component, sequentially from the process of forming the contact hole 203 by dry etching. Also, the process of removing the fluorine-containing organic film 204 remaining in the contact hole 203 can be performed simultaneously with the process of removing the second resist pattern 206. Therefore, the substantial number of process steps greatly decreases.

What is claimed:

1. A method for fabricating a semiconductor device, comprising the step of:
depositing a fluorine-containing organic film having a relative dielectric constant of 4 or less on a semiconductor substrate using a material gas containing C₄F₆ as a main component.

2. A method for fabricating a semiconductor device, comprising the steps of:
dry-etching an insulating film on a semiconductor substrate using an etching gas containing C₄F₆ as a main component; and
depositing a fluorine-containing organic film having a relative dielectric constant of 4 or less on the semiconductor substrate using a material gas containing C₄F₆ as a main component,
wherein the step of dry-etching an insulating film and the step of depositing a fluorine-containing organic film are performed in a same plasma processing apparatus.

3. The method for fabricating a semiconductor device of claim 2, wherein the step of dry-etching an insulating film and the step of depositing a fluorine-containing organic film are performed in a same reactor chamber of the same plasma processing apparatus.

4. The method for fabricating a semiconductor device of claim 2, wherein the step of dry-etching an insulating film includes the step of forming a contact hole through the insulating film,
the step of depositing a fluorine-containing organic film includes the step of filling at least a bottom portion of the contact hole with the fluorine-containing organic film, and
after the step of depositing a fluorine-containing organic film, the method further comprises the step of:
forming a resist pattern having an opening for wiring groove formation on the insulating film;
forming a wiring groove on the insulating film by dry-etching the insulating film using the resist pattern as a mask:
removing the resist pattern and the fluorine-containing organic film existing in the contact hole; and
filling the contact hole and the wiring groove with a metal film to form a contact and a metal interconnection made of the metal film.

5. The method for fabricating a semiconductor device of claim 2, wherein the insulating film is made of a silicon oxide film.

6. A method for fabricating a semiconductor device comprising the steps of:
depositing a metal film on a semiconductor substrate;
forming a mask pattern made of a resist film or an insulating film on the metal film;
dry-etching the metal film using the mask pattern to form a plurality of metal interconnections made of the metal film; and
depositing a fluorine-containing organic film having a relative dielectric constant of 4 or less as an interlayer insulating film between the plurality of metal interconnections and on top surfaces of the metal interconnections using a material gas containing C₄F₆ as a main component.

7. The method for fabricating a semiconductor device of claim 6, wherein the step of forming a mask pattern includes the steps of:
depositing the insulating film on the metal film;
forming a resist pattern on the insulating film; and
dry-etching the insulating film using the resist pattern to form the mask pattern, and
the step of dry-etching the insulating film and the step of depositing a fluorine-containing organic film are performed in a same reactor chamber of a same plasma processing apparatus.

8. The method for fabricating a semiconductor device of claim 7, wherein the step of dry-etching the metal film is performed in the same reactor chamber.

9. The method for fabricating a semiconductor device of claim 8, wherein an inner wall of the reactor chamber includes an aluminum layer and a ceramic layer or an Alumite-treated aluminum layer.

10. The method for fabricating a semiconductor device of claim 7, wherein the insulating film is made of a silicon oxide film.
